(19) United States
(12) Patent Application Publication
(10) Pub. No.: US 2015/0194220 A1
(43) Pub. Date: Jul. 9, 2015

(54) SEMICONDUCTOR DEVICE AND MEMORY SYSTEM INCLUDING THE SAME

(71) Applicant: SK hynix Inc., Gyeonggi-do (KR)

(72) Inventor: Ji Seon YANG, Busan (KR)

(21) Appl. No.: 14/333,181

(22) Filed: Jul. 16, 2014

(30) Foreign Application Priority Data
Jan. 8, 2014 (KR) 10-2014-0002415

(51) Int. Cl. G11C 16/34; G11C 16/26; G11C 16/14

(52) U.S. Cl. CPC G11C 16/3445; G11C 16/14; G11C 16/26; G11C 16/3459

(57) ABSTRACT

A semiconductor device having a memory block which includes a plurality of pages and an operation circuit suitable for performing a program operation on memory cells included in an erase page when the erase page is detected among the plurality of pages through an erase page check operation, and performing an erase loop on the memory block after the program operation.

### CROSS-REFERENCE TO RELATED APPLICATION

The present application claims priority to Korean patent application number 10-2014-0002415, filed on Jan. 8, 2014, the entire disclosure of which is incorporated herein in its entirety by reference.

### BACKGROUND

1. Field of Invention

Various exemplary embodiments of the present invention relate generally to a semiconductor device and a memory system including the same, and more particularly, to a semiconductor device including a memory block and a memory system including the same.

2. Description of Related Art

Semiconductor devices are classified into non-memory semiconductor devices and memory semiconductor devices. Memory semiconductor devices are classified into volatile memory devices and non-volatile memory devices. A NAND flash memory device is a typical non-volatile memory device.

A NAND flash memory device includes a plurality of memory blocks. Each of the memory blocks includes a plurality of pages. A program operation for storing data and a read operation for reading data are performed on each of the pages included in the memory blocks. An erase operation is performed on each of the memory blocks included in the memory device.

### SUMMARY

Two or more bits of data may be stored in a single memory cell in order to store larger amounts of data in a limited space. Therefore, the number of threshold voltage distributions may be determined according to the number of bits of data stored in the single memory cell. For example, when two-bit data is stored in a single memory cell, the distributions of threshold voltages of memory cells are divided into an erase level and first to third program levels.

Exemplary embodiments of the present invention are directed to a semiconductor device with improved memory cell program and erase characteristics and a memory system including the same.

A semiconductor device according to an embodiment of the present invention may have a memory block including a plurality of pages and an operation circuit suitable for performing a program operation on memory cells included in an erase page when the erase page is detected, among the plurality of pages through an erase page check operation, and performing an erase loop on the memory block after the program operation.

A memory system in an embodiment of the present invention may include a semiconductor device including a plurality of memory blocks and a memory controller suitable for providing a command signal and an address signal to the semiconductor device, wherein the semiconductor device performs an erase page check operation to detect an erase page among a plurality of pages included in a selected memory block, performs a program operation on memory cells included in the erase page, and performs an erase loop on the selected memory block after the program operation.

A semiconductor device according to an embodiment of the present invention may include a memory block including a plurality of pages, and an operation circuit suitable for detecting one or more erase pages in the memory block, performing a program operation on the erase pages, and performing an erase loop on the memory block.

### BRIEF DESCRIPTION OF THE DRAWINGS

FIG. 1 is a block diagram illustrating a semiconductor device according to an embodiment of the present invention;

FIG. 2 is a circuit diagram illustrating a memory array shown in FIG. 1;

FIG. 3 is a circuit diagram illustrating a read/write circuit shown in FIG. 1;

FIG. 4 is a flowchart illustrating a method of operating a semiconductor device according to an embodiment of the present invention;

FIGS. 5A to 5D are distribution charts illustrating a method of operating a semiconductor device according to an embodiment of the present invention;

FIG. 6 is a block diagram illustrating a memory system according to an embodiment of the present invention;

FIG. 7 is a block diagram illustrating a fusion memory device or a fusion memory system according to an embodiment of the present invention; and

FIG. 8 is a block diagram illustrating a computing system according to an embodiment of the present invention.

### DETAILED DESCRIPTION

Various exemplary embodiments of the present invention will be described in detail with reference to the accompanying drawings. The figures are provided to enable those of ordinary skill in the art to make and use the present invention according to the exemplary embodiments. Throughout the disclosure, reference numerals correspond directly to the like numbered parts in the various figures and embodiments of the present invention. In addition, a singular form may include a plural form, and vice versa, so long as it is not specifically mentioned.

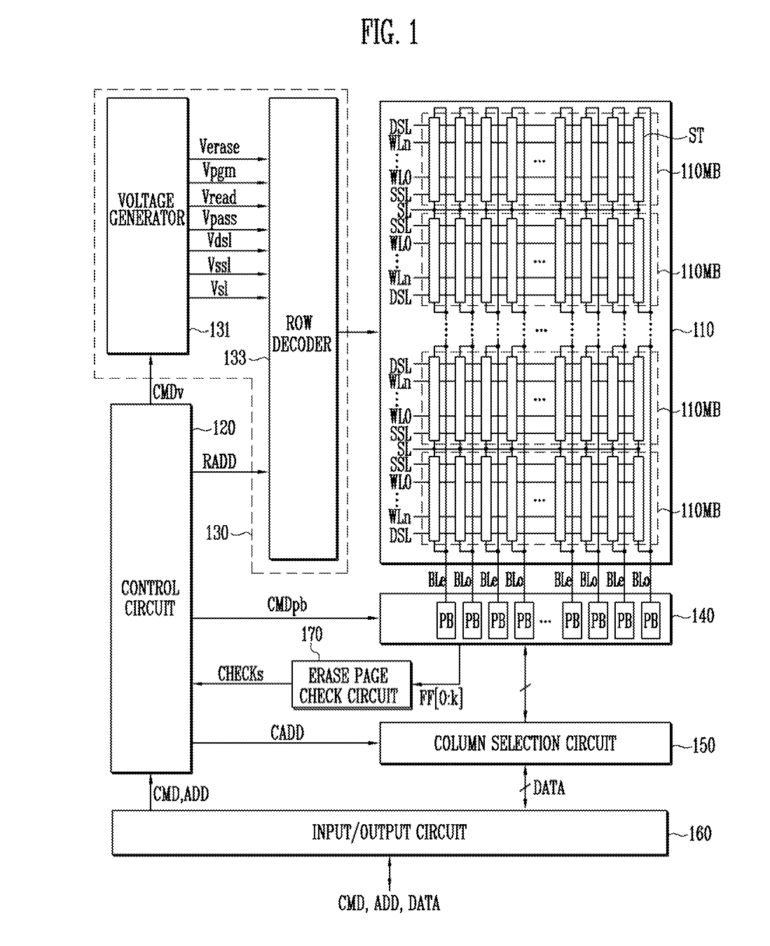

FIG. 1 is a diagram illustrating a semiconductor device according to an embodiment of the present invention.

Referring to FIG. 1, the semiconductor device may include a memory array 110 and operation circuits 120 to 170.

The memory array 110 may include a plurality of memory blocks 110 MB. The structure of the memory blocks 110 MB is described below.

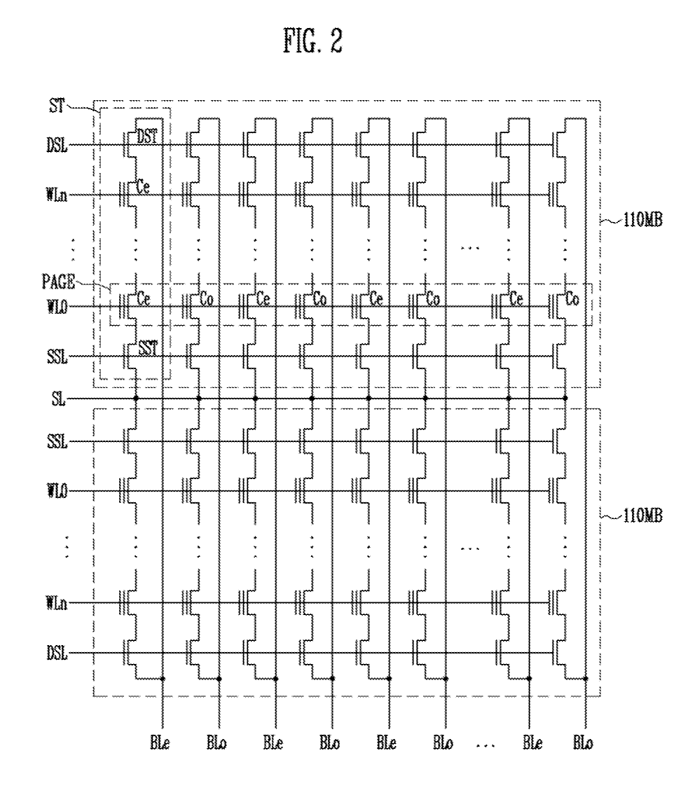

FIG. 2 is a diagram illustrating the memory array shown in FIG. 1.

Referring to FIG. 2, each of the memory blocks 110B may include a plurality of memory strings ST coupled between bit lines BLe and BLo and a common source line SL. In other words, the memory strings ST may be coupled to the bit lines BLe and BLo and coupled in common to the common source line SL. Each of the memory strings ST may include a source selection transistor SST having a source coupled to the common source line SL, a cell string having a plurality of memory cells Ce coupled to each other, and a drain selection transistor DST having a drain coupled to the bit line BLe. The memory cells Ce included in the cell string may be coupled in series between the source and drain selection transistors SST and DST. A gate of the source selection transistor SST may be coupled to the source selection line SSL, gates of the memory cells Ce may be coupled to word lines WL0 to WLn, and a gate of the drain selection transistor DST may be coupled to the drain selection line DSL.

The drain selection transistor DST may control coupling and decoupling of the cell string ST and the bit line BLe or BLo, and the source selection transistor SST may control coupling and decoupling of the cell string ST and the common source line SL.

In a NAND flash memory device, memory cells Ce and Co included in a memory cell block 110 MB may be grouped into a physical page unit or a logical page unit. For example, memory cells Ce and Co coupled to a single word line, for example, the word line WL0 may form a single physical page PAGE. In addition, the even memory cells Ce and the odd memory cells Co coupled to the word line WL0 may respectively form an even page and an odd page, each of which may be a basic unit for a program operation or a read operation.

Referring back to FIG. 1, the operation circuits 120 to 170 may perform a program loop, an erase loop and a read operation on the memory cells Ce and Co coupled to a selected word line, for example, the word line WL0. The program loop may include a program operation and a verify operation. The erase loop may include an erase operation and a verify operation.

In order to perform a program loop, an erase loop and a read operation, the operation circuits 120 to 170 may selectively output operating voltages Verase, Vpgm, Vread, Vpass, Vdsl, Vssl and Vsl to local lines SSL, WL0 to WLn, and DSL of the selected memory block and the common source line SL, and may control precharging and discharging of the bit lines BLe and BLo or sense a current flow through the bit lines BLe and BLo.

In the NAND flash memory device, the operation circuits 120 to 170 may include a control circuit 120, a voltage supply circuit 130, a read/write circuit 140, a column selection circuit 150, an input/output circuit 160 and an erase page check circuit 170. Each of the operation circuits is described in detail below.

In response to a command signal CMD, which is externally input through the input/output circuit 160, the control circuit 120 may output a voltage control signal CMDv to control the voltage supply circuit 130 to generate the operating voltages Verase, Vpgm, Vread, Vpass, Vdsl, Vssl and Vsl for a program loop, an erase loop and a read operation. In addition, the control circuit 120 may output control signals CMDpb for controlling page buffers PB, included in the read/write circuit 140, in order to perform the program loop, the erase loop and the read operation. In addition, when an address signal ADD is input, the control circuit 120 may generate and output a column address signal CADD and a row address signal RADD.

The voltage supply circuit 130 may generate the operating voltages Verase, Vpgm, Vread, Vpass, Vdsi, Vssl and Vsl for the program loop, the erase loop and the read operation on the memory cells in response to the voltage control signal CMDv of the control circuit 120. The voltage supply circuit 130 may output the operating voltages to the local lines SSL, WL0 to WLn, and DSL of the selected memory block and the common source line SL in response to the row address signal RADD of the control circuit 120.

The voltage supply circuit 130 may include a voltage generator 131 and a row decoder 133. The voltage generator 131 may generate the operating voltages Verase, Vpgm, Vread, Vpass, Vdsl, Vssl and Vsl in response to the voltage control signal CMDv of the control circuit 120. The row decoder 133 may transfer the operating voltages to the local lines SSL, WL0 to WLn, and DSL of the selected memory block among the memory blocks 110 MB, and the common source line SL in response to the row address signal RADD of the control circuit 120.

As described below, the voltage supply circuit 130 may appropriately output the operating voltages Verase, Vpgm, Vread, Vpass, Vdsl, Vssl and Vsl in response to the voltage control signal CMDv of the control circuit 120.

The read/write circuit 140 may include a plurality of page buffers PB coupled to the memory array 110 through the bit lines BLe and BLo. Each of the page buffers PB may be coupled to each of the bit lines BLe and BLo. In other words, a single page buffer PB may be coupled to a single bit line. The page buffers PB may selectively precharge the bit lines BLe and BLo in response to the PB control signal CMDpb of the control circuit 120 and data DATA to be stored in the memory cells during a program operation. The page buffers PB may precharge the bit lines BLe and BLo, sense a voltage variation or current of the bit lines BLe and BLo, and latch data read out from the memory cells during a program verify operation or a read operation in response to the PB control signal CMDpb of the control circuit 120.

The page buffers PB may output check signals FF[0:k] to the erase page check circuit 170 to inform an erase state of a selected page on the basis of the data read out from the memory cells of the selected page during an erase page check operation. In addition, the page buffers PB may output check signals FF[0:k] to the erase page check circuit 170 in response to the data read out from the memory cells of the selected page during a program verify operation or an erase verify operation. The operations of the page buffers PB will be described in more detail below.

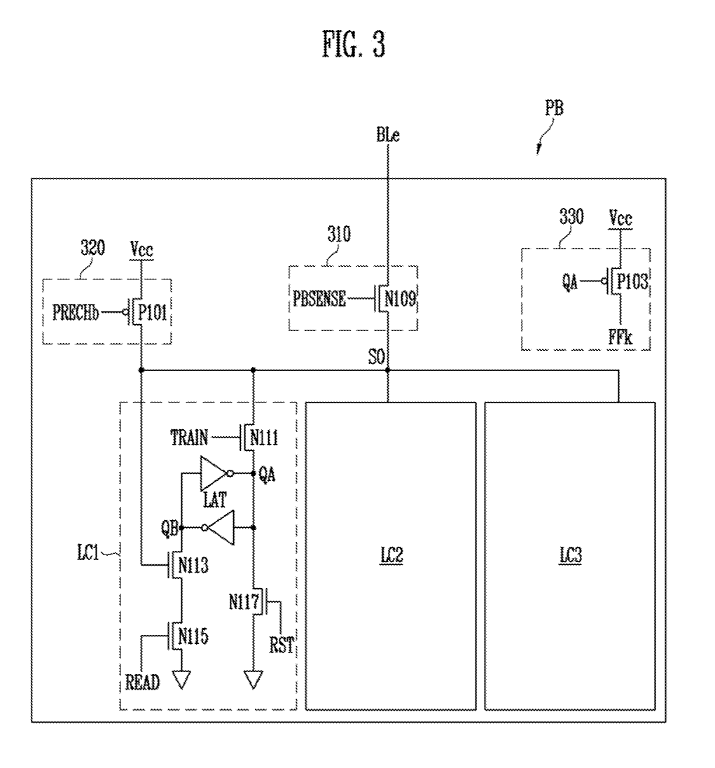

FIG. 3 is a circuit diagram illustrating the read/write circuit shown in FIG. 1.

Referring to FIG. 3, the page buffer PB of the read/write circuit 140 may operate in response to the control signal CMDpb of the control circuit 120 shown in FIG. 1. The control signal CMDpb may include signals PRECHb, PBSENSE, TRAN, READ and RST, which are to be described below.

The page buffer PB may include a bit line coupling circuit 310, a precharge circuit 320, a plurality of latch circuits LC1 to LC3, and a check signal output circuit 330.

The bit line coupling circuit 310 may couple one of the latch circuits LC1 to LC3 to the bit line BLe in response to a connection signal PBSENSE. The connection signal PBSENSE may be applied at different levels when the bit line BLe is precharged and when a voltage level of the bit line BLe is sensed. The bit line coupling circuit 310 may include a switching device N109 operating in response to the connection signal PBSENSE. The latch circuits LC1 to LC3 may be coupled in parallel with the switching device N109. A connecting node between the bit line coupling circuit 310 and the latch circuits LC1 to LC3 may be a sensing node SO.

The precharge circuit 320 may include a switching device P101. The switching device P101 may be coupled between a power voltage and the sensing node SO, and operate in response to a precharge signal PRECHb. The precharge circuit 320 may precharge the sensing node SO. A voltage Vcc, with which the sensing node SO may be precharged, may be a precharge voltage to precharge the bit line BL. In other words, the precharge circuit 320 may output the precharge voltage to precharge the sensing node SO or the bit line BL.

The number of latch circuits LC1 to LC3 may vary depending on a design purpose. FIG. 3 exemplifies three latch circuits LC1 to LC3. In general, only one of the latch circuits LC1 to LC3 may be activated. The second latch circuit LC2 may serve as a cache latch circuit that temporarily stores externally input data and transfers the temporarily stored data to the latch circuit LC3, or may temporarily store the data, which is read from the memory cells, and output the temporarily stored data to an external device during a read operation. The third latch circuit LC3 may apply a program inhibition voltage or a program permission voltage to the bit line BL on the basis of the data transferred from the second latch circuit LC2 during a program operation. In addition, the third latch circuit LC3 may temporarily store the data read out from the memory cells and transfer the temporarily stored data to the second latch circuit LC2 in response to a voltage of the bit line BL during the read operation.

The first latch circuit LC1 may latch the data read from the memory cells and output the latched data to a first node QA during an erase page check operation. In addition, the first latch circuit LC1 may latch a result value of a comparison between a threshold voltage of the memory cell and a target voltage, and output a comparison result signal corresponding to the comparison result value to the first node QA during an erase verify operation or a program verify operation.

Latch circuits may include a plurality of switching devices and a latch. A description is made in reference to an example of the first latch circuit LC1.

The first latch circuit LC1 may include a latch LAT, a switching device N111, a switching device N113, a switching device N115 and a switching device N117. The latch LAT may latch data. The switching device N111 may couple a non-inverting terminal QA of the latch LAT to the sensing node SO in response to a transfer signal TRAN. The switching device N113 may be coupled to an inverting terminal QB of the latch LAT, and operate in response to a voltage of the sensing node SO. The switching device N115 may be coupled between the switching device N113 and a ground voltage, and operate in response to a read signal READ. The switching device N117 may be coupled between the non-inverting terminal QA of the latch LAT and a ground voltage, and operate in response to a reset signal RST. The latch LAT may be initialized in response to the reset signal RST, and the non-inverting node QA may become a low level.

Since signals having different waveforms are applied to the latch circuits LC2 and LC3, only one latch circuit may be activated or the latch circuits LC1, LC2 and LC3 may perform different functions despite the same architecture.

The check signal output circuit 330 may include a switching device P103. The switching device P103 may be coupled between the power voltage and an output node of the page buffer PB, and operate in response to a signal output from the non-inverting terminal QA of the latch LAT.

During the erase page check operation, the bit line BL may be discharged when the data stored in the memory cell is erase data, and may remain precharged when the data stored in the memory cell is program data. The potential of the sensing node SO may be determined by the potential of the bit line BLe through the bit line coupling circuit 310. In response to the potential of the sensing node SO and the read signal READ, the non-inverting node QA of the latch LAT may be maintained at a low level when the data of the memory cell is erase data, and may be changed to a high level through turn-on of the switching devices N113 and N115 when the data is program data.

The check signal output circuit 330 may output the power voltage Vcc as the check signal FFk according to a potential of the non-inverting node QA of the latch LAT when the data of the memory cell is erase data, and may set the output node of the page buffer PB, from which the check signal FFk is output, to a floating state in response to the potential of the non-inverting node QA of the latch LAT when the data of the memory cell is program data. In other words, the page buffer PB may not output the check signal FFk when the data of the memory cell is program data.

During the program verify operation or the erase verify operation, the bit line BL may be discharged when the threshold voltage of the memory cell is lower than the target voltage, and the bit line BL may remain precharged when the threshold voltage of the memory cell is higher than the target voltage. The potential of the sensing node SO may be determined according to the potential of the bit line BL through the bit line coupling circuit 310. In response to the potential of the sensing node SO and the read signal READ, the non-inverting node QA of the latch LAT may be maintained at a low state (program fail state) when the threshold voltage of the memory cell is lower than the target voltage, and may be changed to a high state (program pass state) through turn-on of the switching devices N113 and N115 when the threshold voltage of the memory cell is higher than the target voltage.

The check signal output circuit 330 may output the power voltage Vcc as the check signal FFk in response to the potential of the non-inverting node QA of the latch LAT when the memory cell is in the program fail state, and may set the output node of the page buffer PB, from which the check signal FFk is output, to a floating state in response to the potential of the non-inverting node QA of the latch LAT when the memory cell is in the program pass state. In other words, the page buffer PB may not output the check signal FFk when the memory cell is in the program pass state.

Referring again to FIG. 1, the column selection circuit 150 may select the page buffers PB of the read/write circuit 140 in response to the column address CADD output from the control circuit 120. In other words, the column selection circuit 150 may transfer data to be stored in the memory cells to the page buffers PB in response to the column address CADD. In addition, the column selection circuit 150 may sequentially select the page buffers PB in response to the column address CADD so that the data of the memory cells, which is latched in the page buffers PB, may be externally output during the read operation.

The input/output circuit 160 may transfer the command signal CMD and the column address signal CADD, which are input from an external device to the control circuit 120. In addition, the input/output circuit 160 may transfer the data DATA, which is input from an external device, to the column selection circuit 150 during the program operation, and may externally output the data read out from the memory cells during the read operation.

The erase page check circuit 170 may sense the amount of current varying according to the check signals FF[0:k] output from the page buffers PB after the program verify operation for determining program pass/fail, the erase verify operation for determining erase pass/fail, or the read operation for determining an erase state of a page, is performed on the memory cells. The erase page check circuit 170 may output a check result value CHECKs to the control circuit 120 in response to the check signals FF[0:k].

In accordance with an embodiment of the present invention, the semiconductor device may perform an erase page check operation to detect an erase page among the plurality of pages included in the memory block 110 MB, perform a program operation on memory cells included in the erase page when the erase page is detected by the erase page check operation, and perform an erase loop on the memory block.

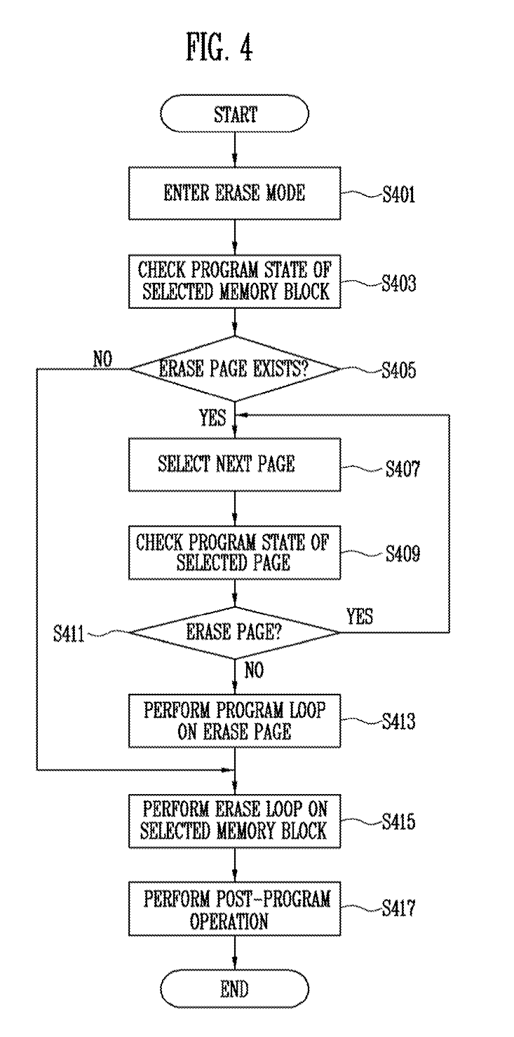

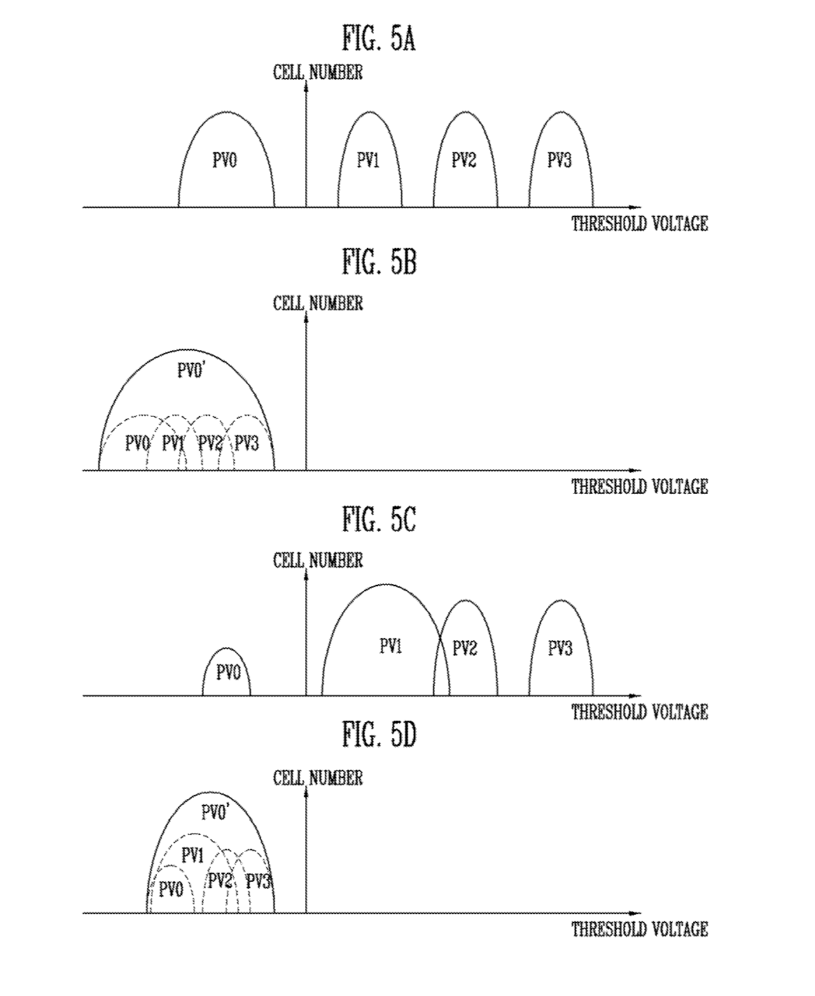

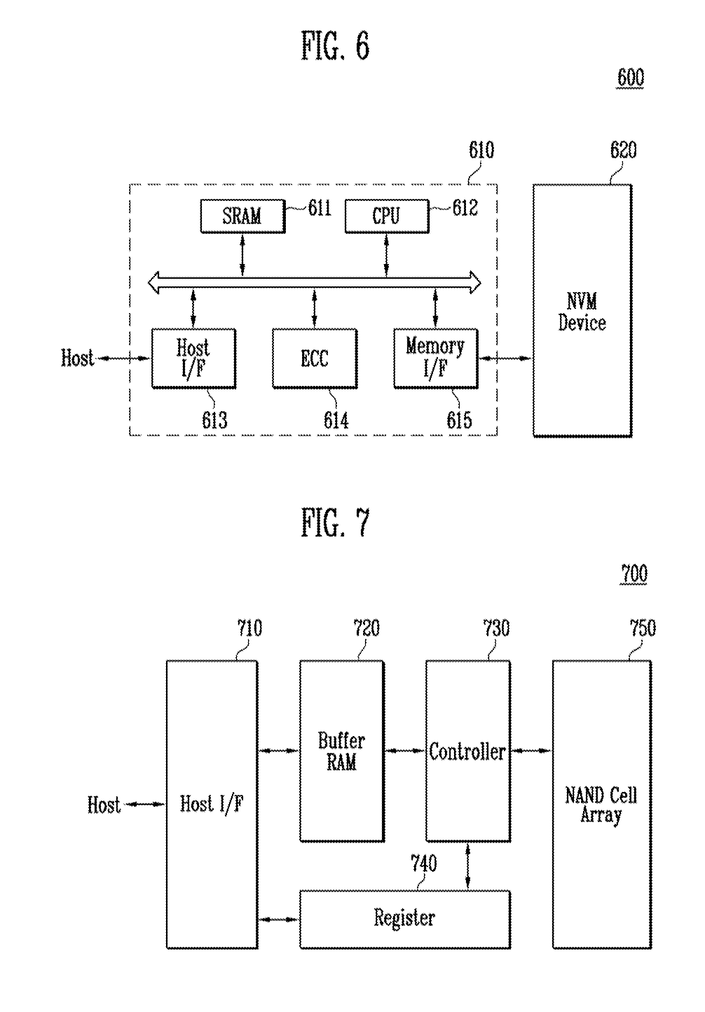

FIG. 4 is a flowchart illustrating a method of operating a semiconductor device according to an embodiment of the present invention. FIGS. 5A to 5D are distribution charts illustrating a method of operating a semiconductor device according to an embodiment of the present invention.

Referring to FIG. 5A, when two-bit data is stored in a unit cell, the distributions of threshold voltages of memory cells included in a memory block may be divided into an erase level PV0 and first to third program levels PV1 to PV3 depending on the data stored in the memory cells.

Referring to FIG. 5B, when the erase loop of the memory block is completed, the threshold voltages of the memory cells may be distributed at an erase level PV0′. While the erase loop is performed, the threshold voltages of the memory cells originally distributed at the erase level PV0 may be lower than an erase verify level, and the threshold voltages of the memory cells originally distributed at the program levels PV1 to PV3 may be decreased to the erase verify level. As a result, a threshold voltage distribution at the erase level PV0′ after the erase loop may be wider than the original erase level PV0.

A post-program operation may be performed in order to narrow the threshold voltage distribution of the erase level PV0′. However, electrical characteristics of the memory cells may be deteriorated due to an increase of write/erase cycling number caused by the post-program operation. In addition, when a memory cell having the lowest threshold voltage at the erase level PV0′ is programmed to the highest program level during the post-program operation, the influence on variations in threshold voltages of neighboring memory cells may be increased.

An operating method in accordance with an embodiment of the present invention capable of minimizing the increase of write/erase cycling number of memory cells and narrowing the threshold voltage distribution of the erase level PV0′ will be described below.

Referring to FIGS. 1 and 4, the semiconductor device may enter an erase mode in order to erase the data stored in the memory cells of the selected memory block at step S401. The semiconductor device may enter the erase mode prior to the program operation.

A program state of the selected memory block may be checked at step S403. In other words, an operation may be performed to check whether data is stored in every page included in the selected memory block. In other words, it may be checked whether there is an erase page, which does not include data and maintains an erase state since the program operation has not been performed thereon, among the pages of the selected memory block.

The operation circuits 120 to 170 may perform the erase page check operation in order to detect the erase page. The erase page check operation of step S405 may be performed by detecting an erase page, which corresponds to the last address, among the pages included in the selected memory block. The erase page check operation of step S405 is described in detail below.

When the erase mode is entered in response to the erase command CMD, the control circuit 120 may output the row address RADD in order to select the last page of the selected memory block in response to the address ADD. In addition, the control circuit 120 may output the control signals CMDpb to the read/write circuit 140 in order to control the page buffers PB of the read/write circuit 140. The erase command CMD and the address signal ADD may be input to the control circuit 120 from an external controller through the input/output circuit 160.

The read/write circuit 140 may precharge the bit lines BLe and BLo in response to the control signals CMDpb of the control circuit 120. When the erase page check operation is performed on each of the even pages and odd pages, the read/write circuit 140 may precharge only selected bit lines BLe or BLo.

The voltage generator 131 may output voltages (e.g., Vread, Vpass, Vdsl, Vssl and Vsl) for the erase page check operation in response to the voltage control signal CMDv of the control circuit 120. The row decoder 133 may apply the voltages Vread, Vpass, Vdsl, Vssi and Vsi from the voltage generator 131 to the local lines SL, SSL, WL0 to WLn, and DSL of the selected memory block 110 MB in response to the row address signal RADD of the control circuit 120.

A read voltage Vread, which has a level distinguishing the lowest program level among the program levels from the erase level, may be applied to the memory cells of the last page. In other words, the read voltage Vread may be applied to the last word line WLn. A pass voltage Vpass may be applied to the remaining pages (or remaining word lines). Selection voltages Vdsl and Vssi having positive potentials may be applied to the drain and source selection lines DSL and SSL, respectively. A ground voltage may be applied as a common source voltage Vsl to the common source line SL.

When the last page is the erase page that does not store data since the program operation has not been performed thereon, all the memory cells included in the last page may store erase data. As a result, the bit lines BLe and BL0 may be discharged. When the last page is the program page that stores data, since the program operation has been performed thereon, some of the memory cells included in the last page may store program data. As a result, some of the bit lines BLe and BL0 may remain precharged.

The read/write circuit 140 may sense potentials of the bit lines BLe and BL0, latch sensing results, and output the check signals FF[0:k] according to the latched sensing results. The erase page check circuit 170 may output the check result value CHECKs to the control circuit 120 to inform whether the last page is the erase page or the program page based on the check signals FF[0:k].

Referring back to FIG. 4, the erase page may be detected in the selected memory block at step S405. The control circuit 120 may check whether the last page is the erase page or the program page on the basis of the check result value CHECKs of the erase page check circuit 170.

When it is detected that the last page is the erase page at step S405, the control circuit 120 may perform an additional erase page check operation at steps S407, S409 and S411 in order to detect another erase page in the selected memory block. The additional erase page check operation is described in detail below.

A subsequent page in the selected memory block may be selected at step S407. For example, the control circuit 120 may output the row address signal RADD indicating a reduced page address in response to the check result value CHECKs of step S405.

A program state of the selected page may be checked at step S409 on the basis of the reduced page address. In other words, an operation may be performed to check whether the selected page is the erase page or the program page. To perform such operation, the data stored in the memory cells of the selected page may be read.

The program state of the selected page may be determined at step S411 on the basis of the data read from the selected page at step S409. In other words, it may be determined whether the selected page is the erase page. The data read operation at step S409 and the page determination operation at step S411 may be performed by the method described above with reference to steps S403 and S405.

The selected page may be determined as the erase page at step S411. The control circuit 120 may perform the determination operation of step S411 on the basis of the check result value CHECKs of the erase page check circuit 170 at step S409. When the selected page is determined as the erase page, the above-described steps S407, S409 and S411 may be repeated in order to detect another erase page in the selected memory block. In other words, steps S407, S409 and S411 may be repeated until the selected page is determined as the program page at step S411.

Referring to FIGS. 1, 4 and 5C, when the selected page is determined as the program page at step S411, program operations may be performed on the erase pages, which are determined at steps S405 and S411, at step S413. The program operations of the erase pages may be sequentially performed in response to the page addresses, or may be performed at the same time. The program operations performed on the erase pages are described below.

The control circuit 120 may output the voltage control signal CMDv to the voltage generator 131, the row address RADD to the row decoder 133, and the control signals CMDpb to the read/write circuit 140.

The read/write circuit 140 may discharge the bit lines BLe and BLo in response to the control signals CMDpb of the control circuit 120. When the program operation is performed on each of the even pages and odd pages, the read/write circuit 140 may discharge only the selected bit lines BLe or BLo.

The voltage generator 131 may output voltages (e.g., Vpgm, Vpass, Vdsl, Vssl and Vsl) for the program operation in response to the voltage control signal CMDv of the control circuit 120. The row decoder 133 may apply the voltages from the voltage generator 131 to the local lines SL, SSL, WL0 to WLn, and DSL of the selected memory block 110 MB in response to the row address signal RADD of the control circuit 120.

A program voltage Vpgm may be applied to memory cells of a selected erase page or memory cells of all erase pages. In other words, the program voltage Vpgm may be applied sequentially to the word line of the selected erase page among the erase pages, or simultaneously to word lines of the erase pages. The pass voltage Vpass may be applied to word lines of remaining program pages. The selection voltage Vdsl having a positive potential may be applied to the drain selection line DSL. The selection voltage Vssl of a ground voltage may be applied to the source selection line SSL. The power voltage may be applied as the common source voltage Vsl to the common source line SL.

After the program operation is performed under the above-described conditions, a program verify operation may be performed. In other words, the program verify operation may be performed in order to check if threshold voltages of memory cells included in the erase pages are higher than the target voltage (e.g., OV). The program operation and the program verify operation may be repeated by using the Increment Step Pulse Program (ISPP) method.

The read/write circuit 140 may output the check signals FF[0:k] as verify results of the memory cells during the program verify operation. The erase page check circuit 170 may output the check result value CHECKs to the control circuit 120 to inform the success/failure of performing the program operation based on the check signals FF[0:k].

When the program operations of the erase pages are completed, the distribution of threshold voltages of the memory cells included in the erase pages may move to a program level (e.g., PV1). In addition, only the threshold voltages of a few memory cells storing normal erase data among the program pages may remain at the original erase level PV0.

Referring to FIGS. 1, 4 and 5D, when the last page is determined as the program page at step S405 or the program operations of the erase pages at step S413 are completed, an erase loop of a memory block may be performed at step S415. First, during an erase operation, a ground voltage may be applied to the word lines WL0 to WLn, and an erase voltage may be applied to a bulk (P well or substrate) of the memory cells. The erase operation is well-known in the art. Subsequently, an erase verify operation may be performed to check whether the erase operation is successful or not. The erase operation and the erase verify operation may be repeated according to the Increment Step Pulse Erase (ISPE) method.

During the erase verify operation, the read/write circuit 140 may output the check signals FF[0:k] as the verify results of the memory cells. The erase page check circuit 170 may output the check result value CHECKs to the control circuit 120 to inform whether the erase operation is successful based on the check signal FF[0:k].

When the erase loop at step S415 is completed, the distributions of all the threshold voltages of the memory cells of the memory block may move to the erase level PV0′. As described above, the erase loop may be performed at step S415 after the distribution of threshold voltages of the memory cells of the erase page are increased by the program operation on the erase pages at step S413. Therefore, the erase level PV0′ of FIG. 5D due to an embodiment of the present invention may be narrower than the existing erase level PV0′ of FIG. 5B.

A post-program operation may be optionally performed at step S417. The post-program operation may be performed to further reduce the threshold voltage distribution of the erase cells on which the erase loop is completed. The post-program operation is well-known in the art. Since the threshold voltage distribution of the erase cells is narrowed by the program operation on the erase pages, the post-program operation may be omitted.

FIG. 6 is a block diagram illustrating a memory system according to an embodiment of the present invention.

As illustrated in FIG. 6, a memory system 600 according to an embodiment of the present invention may include a non-volatile memory device 620 and a memory controller 610.

The non-volatile memory device 620 may include the above-described semiconductor memory. In addition, the memory controller 610 may output the erase command CMD and the address signal ADD, which are described at step S404 In FIG. 4, to the non-volatile memory device 620. In other words, the memory controller 610 may control the non-volatile memory device 620. The memory controller 610 may be a solid state disk (SSD) or a memory card in which the non-volatile memory device 620 and the memory controller 610 are combined. SRAM 611 may function as an operation memory of a processing unit 612. A host interface 613 may include a data exchange protocol of a host being coupled to the memory system 600. An error correction block 614 may detect and correct errors included in a data read from the non-volatile memory device 620. A memory interface 614 may interface with the non-volatile memory device 620. The processing unit 612 may perform the general control operation for data exchange of the memory controller 610.

Though not shown in FIG. 6, the memory system 600 may further include ROM (not illustrated) that stores code data to interface with the host. In addition, the non-volatile memory device 620 may be a multi-chip package composed of a plurality of flash memory chips. The memory system 600 having the above-described configuration may be provided as a storage medium having high reliability and low error rate. When a flash memory device according to an embodiment of the present invention is provided in a memory system such as a semiconductor disk device (solid state disk (SSD)) on which research has been actively conducted, the memory controller 610 may communicate with an external device (e.g., a host) through one of various interface protocols, such as USB, MMC, PCI-E, SATA, PATA, SCSI, ESDI and IDE.

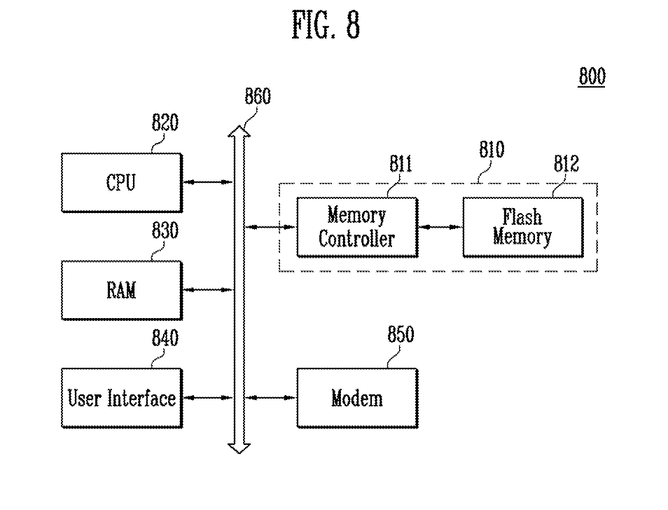

FIG. 7 is a block diagram illustrating a fusion memory device or a fusion memory system according to an embodiment of the present invention. For example, technical features of the present invention may be applied to a OneNAND flash memory device 700 as a fusion memory device.

The OneNand flash memory device 700 may include a host interface (I/F) 710, a buffer RAM 720, a controller 730, a register 740 and a NAND flash cell array 750. The host interface 710 may exchange various types of information with a device using different protocols. The buffer RAM 720 may be loaded with codes for driving the memory device or temporarily storing data. The controller 730 may control read and program operations at every state in response to a control signal and a command that are externally given. The register 740 may be configured to store data including instructions, addresses and configurations defining a system operating environment in the memory device. The NAND flash cell array 750 may include operating circuits including non-volatile memory cells and page buffers. The memory array shown in FIG. 2 may be used as a memory array of the NAND flash cell array 750.

FIG. 8 is a block diagram illustrating a computing system according to an embodiment of the present invention. The computing system 800 may include a flash memory device 812.

The computing system 800 according to an embodiment of the present invention may include a microprocessor 820, RAM 830, a user interface 840, a modem 850, such as a baseband chipset, and a memory system 810, all of which are electrically coupled to a system bus 860. In addition, when the computing system 800 is a mobile device, a battery (not illustrated) may be further included to apply an operating voltage to the computing system 800. Though not shown in FIG. 8, the computing system 800 may further include application chipsets, a camera image processor (CIS) and mobile DRAM. The memory system 810 may form a solid state drive/disk (SSD) that uses a non-volatile memory device in order to store data. Alternatively, the memory system 810 may be provided as a fusion memory flash memory (e.g., OneNAND flash memory).

According to an embodiment of the present invention, program and erase characteristics of a memory cell may be improved.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. A semiconductor device, comprising:
a memory block including a plurality of pages; and
an operation circuit suitable for performing a program operation on memory cells included in an erase page when the erase page is detected among the plurality of pages through an erase page check operation, and performing an erase loop on the memory block after the program operation.

2. The semiconductor device of claim 1, wherein the operation circuit checks data of memory cells included in a page corresponding to a last address among the plurality of pages during the erase page check operation for detecting the erase page.

3. The semiconductor device of claim 1, wherein the operation circuit further performs an additional erase page check operation to detect other erase pages when the erase page is detected through the erase page check operation.

4. The semiconductor device of claim 3, wherein the operation circuit repeats performing the additional erase page check operation by decreasing a page address.

5. The semiconductor device of claim 4, wherein the operation circuit repeats decreasing the page address and performing the additional erase page check operation until it is checked that a page selected by a decreased page address is a program page.

6. The semiconductor device of claim 3, wherein during the additional erase page check operation, the operation circuit decreases a page address, reads data stored in memory cells of a page selected by a decreased page address, and checks whether the selected page is the erase page by using read data.

7. The semiconductor device of claim 3, wherein the operation circuit performs program operations simultaneously on the erase pages detected by the additional erase page check operation.

8. The semiconductor device of claim 3, wherein the operation circuit performs program operations sequentially on the erase pages detected by the additional erase page check operation according to a page address.

9. The semiconductor device of claim 1, wherein the operation circuit further performs a post-program operation on the memory block after the erase loop.

10. The semiconductor device of claim 1, wherein the operation circuit comprises:
a read/write circuit suitable for reading data stored in memory cells of a page; and
an erase page check circuit suitable for checking whether the page is the erase page on the basis of the data read out by the read/write circuit.

11. The semiconductor device of claim 10, wherein the erase page check circuit further checks whether an erase operation is successful or not during an erase verify operation, or whether a program operation is successful or not during a program verify operation.

12. A memory system, comprising:
a semiconductor device including a plurality of memory blocks; and
a memory controller suitable for providing a command signal and an address signal to the semiconductor device,
wherein the semiconductor device performs an erase page check operation to detect an erase page among a plurality of pages included in a selected memory block, performs a program operation on memory cells included in the erase page, and performs an erase loop on the selected memory block after the program operation.

13. The memory system of claim 12, wherein the semiconductor device checks data of memory cells included in a page corresponding to a last address among the plurality of pages during the erase page check operation for detecting the erase page.

14. The memory system of claim 12, wherein the semiconductor device further performs an additional erase page check operation to detect other erase pages when the erase page is detected through the erase page check operation.

15. The memory system of claim 14, wherein the semiconductor device performs program operations simultaneously on the erase pages detected by the additional erase page check operation.

16. The memory system of claim 14, wherein the semiconductor device performs program operations sequentially on the erase pages detected by the additional erase page check operation according to a page address.

17. The memory system of claim 12, wherein the semiconductor device further performs a post-program operation on the selected memory block after the erase loop.

18. A semiconductor device, comprising:
a memory block including a plurality of pages; and
an operation circuit suitable for detecting one or more erase pages in the memory block, performing a program operation on the erase pages, and performing an erase loop on the memory block.

19. The semiconductor device of claim 18, wherein the operation circuit detects the erase pages by sequentially selecting one from the multiple pages in descending order of their addresses starting from last address in the memory block, and identifying an erase data stored in the selected page.

20. The semiconductor device of claim 19, wherein the operation circuit detects the erase pages until the operation circuit identifies a program data stored in the selected page.
